(19) United States
(12) Patent Application Publication
(10) Pub. No.: US 2013/0234180 A1
(43) Pub. Date: Sep. 12, 2013

(54) LIGHT EMITTING DIODE PACKAGING STRUCTURE

(71) Applicant: Kuan-Yu CHIU, Taoyuan County (TW)

(72) Inventor: Kuan-Yu CHIU, Taoyuan County (TW)

(73) Assignee: LEXTAR ELECTRONICS CORPORATION, Hsinchu (TW)

(21) Appl. No.: 13/571,372

(22) Filed: Aug. 10, 2012

(30) Foreign Application Priority Data
Mar. 12, 2012 (TW) 101108325

(51) Int. Cl. H01L 33/64

(52) U.S. Cl. 257/98; 257/E33.075

(57) ABSTRACT

A light emitting diode packaging structure provided in the invention includes a base, a plurality of lead frames, a LED chip, a thermal conductive film and an encapsulating member. The base includes a reflective recess and a plurality of outer surfaces surrounding the reflective recess. The lead frames are respectively disposed on the base, and exposed from the reflective recess. The LED chip is disposed on one of the lead frames in the reflective recess The thermal conductive film is with a light shielding property, and covers all inner surfaces of the reflective recess and at least one of the outer surfaces of the base. The encapsulating member is disposed in the reflective recess to cover the thermal conductive film and the LED chip.

### RELATED APPLICATIONS

This application claims priority to Taiwan Application Serial Number 101108325, filed Mar. 12, 2012, which is herein incorporated by reference.

### BACKGROUND

1. Technical Field

The present invention relates to a light emitting diode (LED) element, and more particularly to a light emitting diode packaging structure having a thermal conductive film.

2. Description of Related Art

A light emitting diode (LED) is categorized as one of the compound semiconductors, which outputs energy in a light emitting form while the electron holes of P-type and N-type semiconductor materials are combined. Moreover, the light emitting diode has the advantages of small volume, long service life, low power consumption and fast reaction speed, so that light emitting diode has been widely used in an optical display device, communication device and illumination device, for example, and has become a indispensable photoelectric element.

However, the heat dissipation effect of the aforementioned light emitting diode (LED) chip still needs improvement. The poor heat dissipation will cause the material to be deteriorated, thus forming an inferior product which fails to provide an effective solution for better heat dissipation. In addition, if a lateral wall structure of the conventional LED chip is relatively thin in thickness, the light outputted from the lateral wall cannot be effectively shielded, so that the light can be transmitted through resin material, thus lowering the brightness of the alight-emitting surface.

In view of the foregoing, the conventional LED chip has apparent inconvenience and defects, and needs to be improved. Hence, how to effectively solve the aforementioned inconvenience and defects becomes a serious issue to be concerned.

### SUMMARY

The present invention provides a light emitting diode packaging structure for increasing the heat dissipation efficiency, such that the heat generated by LED chip therein can be rapidly dissipated, thereby preventing the service life of light emitting diode packaging structure from being shortened.

The present invention provides a light emitting diode packaging structure served for at least shielding the light emitted from LED chips, thereby preventing the light emitting diode packaging structure from having light leakage due to its excessively thin lateral wall.

The light emitting diode packaging structure provided by the present invention includes a base, a plurality of lead frames, a LED chip, a thermal conductive film and an encapsulating member. The base includes a reflective recess and a plurality of outer surfaces surrounding the reflective recess. The lead frames are respectively disposed in the base, and exposed in the reflective recess. The LED chip is disposed on one of the lead frames in the reflective recess. The thermal conductive film is with a light shielding property, and covers all inner surfaces of the reflective recess and at least one of the outer surfaces of the base. The encapsulating member is filled in the reflective recess to cover the thermal conductive film and the LED chip.

In one exemplary embodiment of the present invention, the thermal conductive film partially covers at least one of the outer surfaces of the base.

In another exemplary embodiment of the present invention, the thermal conductive film completely covers all of the outer surfaces of the base.

In one optionally variation of the exemplary embodiments of the present invention, regardless of the thermal conductive film partially or completely covering the outer surface of the base, the thermal conductive film further covers at least one of the lead frames.

In another variation of the exemplary embodiments of the present invention, regardless of the thermal conductive film partially or completely covering the outer surface of the base, the thermal conductive film further contacts the LED chip.

In another optionally variation of the exemplary embodiments of the present invention, the thermal conductive film is formed as a single-layer or a multiple-layer.

Furthermore, in another optionally variation of the embodiments of the present invention, the thermal conductive film has a thickness smaller than or equal to 100 micrometer.

In yet still another optionally variation of the exemplary embodiments of the present invention, the thermal conductive film comprises one single type of material or a plurality of types of materials.

Also, in another optionally variation of the exemplary embodiments of the present invention, the thermal conductive film comprises an organic material, an inorganic material or a compound material. Also, the material forming the thermal conductive film is diamond-like carbon, aluminum nitride, aluminum oxide or ceramic.

In another optionally variation of the exemplary embodiments of the present invention, the thermal conductive film comprises a plurality of particles, and a diameter of each particle is less than or equal to 10 micrometer.

Moreover, in another optionally variation of the exemplary embodiments of the present invention, the light emitting diode packaging structure further comprises a light reflecting layer covering the thermal conductive film.

It can be seen from the above that, the solution provided by the present invention has obvious advantage and practicability while being compared with the conventional arts, and therefore the present invention can be widely applied in various industries, and at least has the following advantages.

1. The light emitting diode packaging structure provided by the present invention utilizes the configuration of a thermal conductive film to provide a better heat dissipation effect, such that the high temperature generated by a LED chip can be rapidly decreased, thereby preventing the service life of light emitting diode packaging structure from being shortened;

2. The light emitting diode packaging structure provided by the present invention utilizes the light shielding property of the thermal conductive film to prevent light leakage due to the excessively thin lateral wall formed on the light emitting diode packaging structure, thereby preventing the overall emitted light amount of the light emitting diode packaging structure from being reducing;

3. The light emitting diode packaging structure provided by the present invention utilizes the light reflecting property of the thermal conductive film to concentrate the light generated by the LED chip, thereby increasing the overall emitted light amount of the light emitting diode packaging structure.

### BRIEF DESCRIPTION OF THE DRAWINGS

The present invention will be apparent to those skilled in the art by reading the following detailed description of a preferred embodiment thereof, with reference to the attached drawings, in which:

FIG. 1A is a side view showing a light emitting diode packaging structure according to one embodiment of the present invention;

FIG. 1B is a partially enlarged view showing a zone M marked in FIG. 1A;

FIG. 2 is a side view showing a light emitting diode packaging structure according to another embodiment of the present invention;

FIG. 3 is a side view showing a light emitting diode packaging structure according to another embodiment of the present invention;

FIG. 4 is a side view showing a light emitting diode packaging structure according to still another embodiment of the present invention;

FIG. 5 is a side view showing a Light emitting diode packaging structure according to still another embodiment of the present invention;

FIG. 6 is a schematic view showing a thermal conductive film of a light emitting diode packaging structure according to still another embodiment of the present invention; and

FIG. 7 is a schematic view showing a thermal conductive film of a light emitting diode packaging structure according to still another embodiment of the present invention.

### DESCRIPTION OF THE EMBODIMENTS

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

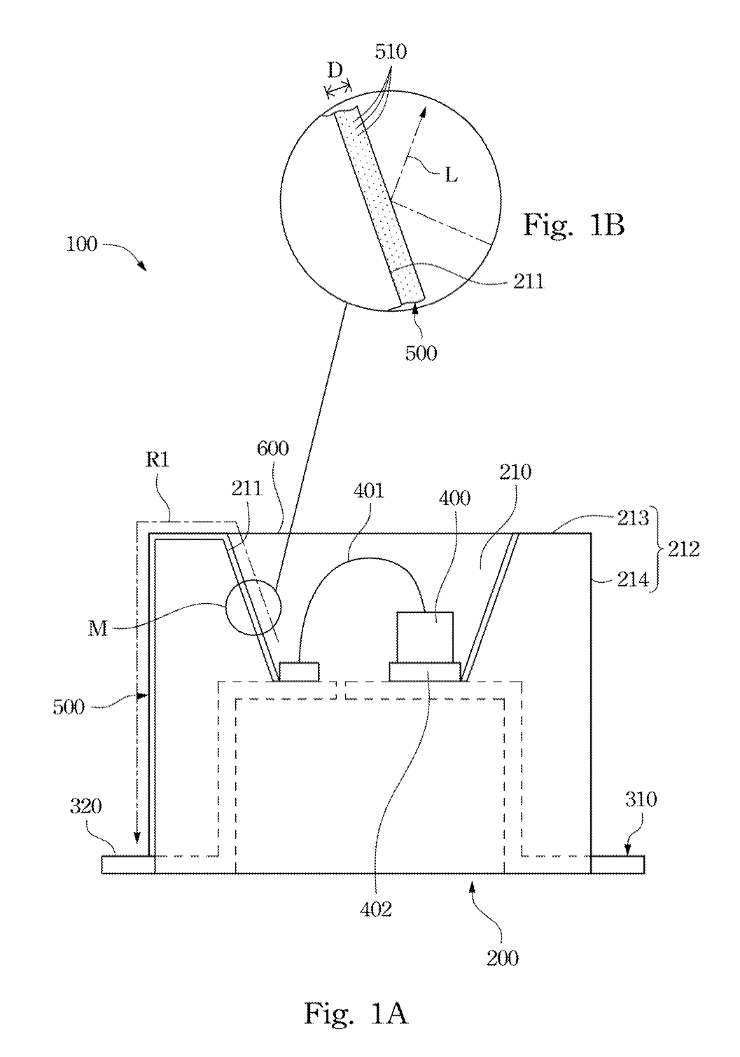

Reference is now made to FIG. 1A and FIG. 1B. FIG. 1A is a side view showing a light emitting diode packaging structure 100 according to one embodiment of the present invention, and FIG. 1B is a partially enlarged view showing a zone M marked in FIG. 1A.

The present invention provides the light emitting diode packaging structure 100. The mentioned light emitting diode packaging structure 100 includes a base 200, a first lead frame 310, a second lead frame 320, a LED chip 400, a thermal conductive film 500 and a encapsulating member 600. The base 200 includes a reflective recess 210, a plurality of inner surfaces 211 and a plurality of outer surfaces 212. The inner surfaces 211 are formed inside the reflective recess 210 and arranged to surround the reflective recess 210. The outer surfaces 212 are generally defined as surfaces of the base 200 disposed outside the reflective recess 210 and arranged to surround the reflective recess 210. A first lead frame 310 and a second lead frame 320 are respectively embedded inside the base 200, and one end of the first lead frame 310 and one end of the second lead frame 320 are respectively disposed in the reflective recess 210 and exposed outwards from the reflective recess 210, and the other end of the first lead frame 310 and the other end of the second lead frame 320 are respectively protruded from two opposite outer surfaces 212 of the base 200.

The LED chip (or dice) 400 is disposed in the reflective recess 210, mounted on one end surface of the first lead frame 310, and electrically connected to a surface of the first lead frame 310. The LED chip 400 is electrically connected to the second lead frame 320 via a conductive wire 401. A thermal conductive film 500 is formed continuously, and at least with a light shielding property, and completely covers (or is coated on) all of the inner surfaces 211 of the reflective recess 210 and continuously covers at least one of the outer surfaces 212 of the base 200.

According to this embodiment, the outer surfaces 212 of the base 200 are defined as a top surface 213 and four lateral surfaces 214. The reflective recess 210 is formed on the top surface 213, and the other end of the first lead frame 310, and the other end of the second lead frame 320 respectively protrude from two opposite lateral surfaces 214.

According to this embodiment, the thermal conductive film 500 partially covers (or is coated on) the outer surfaces 212 of the base 200, and the thermal conductive film 500 is at least extended continuously from the inner surfaces 211 to the top surface 213, or the thermal conductive film 500 is at least extended continuously from the inner surfaces 211 to one of the lateral surfaces 214 via the top surface 213, as shown in FIG. 1. The encapsulating member 600 made by resin or plastic is fully filled in the reflective recess 210, and served to wrap and fix the thermal conductive film 500, the LED chip 400 and the conductive wire 401 therein.

As such, the thermal conductive film 500 is extended continuously from the inner surfaces 211 to the outer surfaces 212, so as to be physically connected to other heat dissipation devices (not shown in figures), such that heat generated by the LED chip 400 can be transferred through the thermal conductive film 500 along a heat conducting path R1 formed on the thermal conductive film 500, so as to be transferred from the reflective recess 210 to the ambience; furthermore, the heat generated by the LED chip 400 can be transferred to the atmosphere along the heat conducting path R1 so as to achieve heat dissipation.

In addition, the thermal conductive film 500 is with the light shielding property and completely covers all of the inner surfaces 211 of the reflective recess 210, such that the thermal conductive film 500 formed on all of the inner surfaces 211 in the reflective recess 210 of the base 200 can be served to at least shield the light L of the LED chip 400, as shown in FIG. 1B, so as to prevent light leakage from overly thin lateral wall of the light emitting diode packaging structure 100.

Moreover, when the thermal conductive film 500 is further with the light reflecting property, the thermal conductive film 500 formed on all of the inner surfaces 211 in the reflective recess 210 of the base 200 can reflect the light L, such that the light L can be concentrated and outputted towards an opening formed in the reflective recess 210, so as to increase the overall emitted light amount of the light emitting diode packaging structure 100.

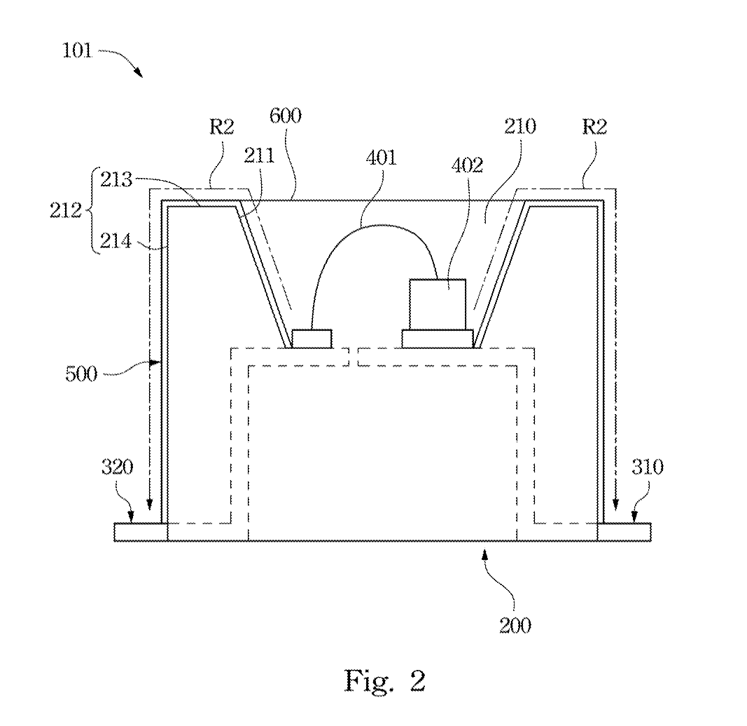

FIG. 2 is a side view showing the light emitting diode packaging structure 101 according to another embodiment of the present invention.

According to another embodiment, the thermal conductive film 500 completely covers all of the outer surfaces 212 of the base 200. Substantially, when the thermal conductive film 500 completely covers (or is coated on) all of the outer surfaces 212 of the base 200, the thermal conductive film 500 is extended continuously from the inner surfaces 211 to all of the top surface 213 and the four lateral surfaces 214, as shown in FIG. 2.

Because the thermal conductive film 500 completely covers all of the outer surfaces 212 of the base 200, the heat generated by the LED chip 400 can be transferred through the thermal conductive film 500 along a heat conducting path R2 formed on the thermal conductive film 500 so as to be transferred from the reflective recess 210 to the ambience (atmosphere), such that a larger heat dissipation area is provided through the thermal conductive film 500; furthermore, the heat generated by the LED chip 400 can be transferred to the atmosphere along the heat conducting path R2 so as to achieve a better heat dissipation effect.

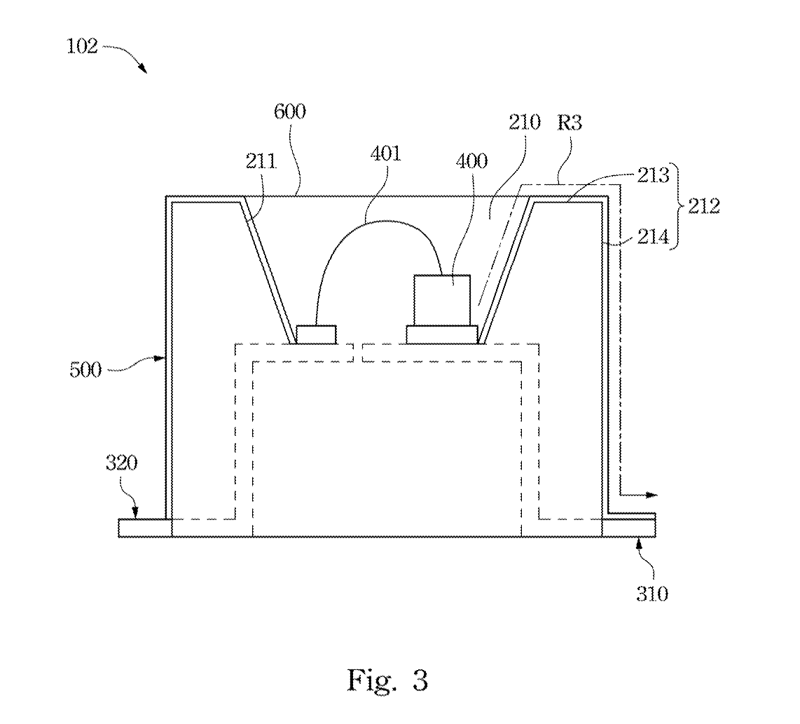

Reference is now made to FIG. 3. FIG. 3 is a side view showing the light emitting diode packaging structure 102 according to another embodiment of the present invention.

According to the one another embodiment, the thermal conductive film 500 further covers (or is coated on) a surface of the other end of the first lead frame 310 which is protruded from the outer surfaces 212. Substantially, the thermal conductive film 500 is extended continuously from the inner surfaces 211 to all of the top surface 213, the full area of the four lateral surfaces 214 and the other end surface of the first lead frame 310 which is protruded from the outer surfaces 212. As such, the heat generated by the LED chip 400 can be transferred through the thermal conductive film 500 along a heat conducting path R3 formed by the thermal conductive film 500, such that the heat generated by the LED chip 400 can be further transferred to the atmosphere through the heat conducting path R3. Furthermore, the heat generated by the LED chip 400 can be transferred to the ambience through the first lead frame 310, so as to provide a better heat conduction effect.

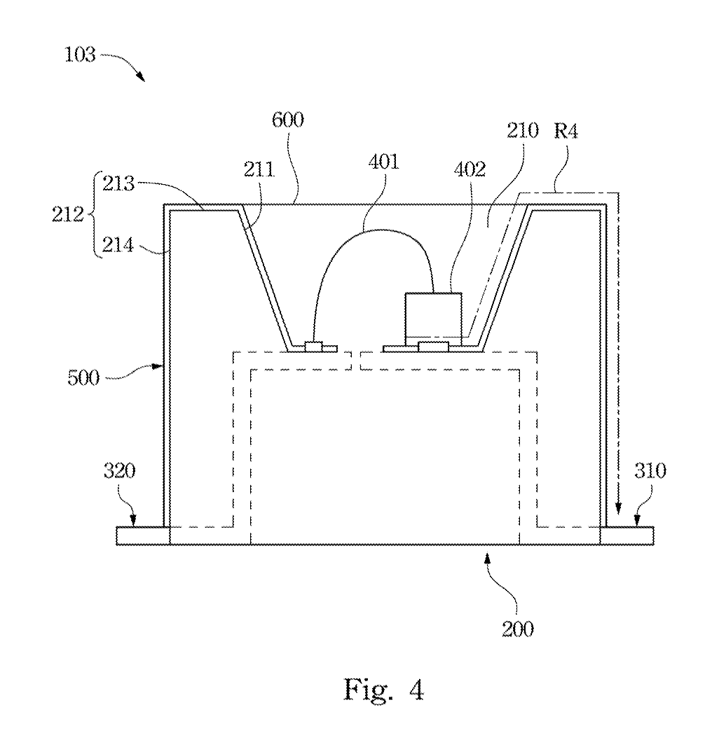

FIG. 4 is a side view showing the light emitting diode packaging structure 103 according to still another embodiment of the present invention.

Regardless of the thermal conductive film 500 partially or completely covering the outer surfaces 212 of the base 200, the thermal conductive film 500 is further in contact with the LED chip 400.

Substantially, the thermal conductive film 500 is extended continuously from the inner surfaces 211 of the base 200 to one end surface of the first lead frame 310 in the reflective recess 210, and the defined portion of thermal conductive film 500 is disposed between the LED chip 400 and the first lead frame 310, so as to be physically in contact with the LED chip 400. As such, the heat generated by the LED chip 400 can be directly transferred through the thermal conductive film 500 along a heat conducting path R4 formed by the thermal conductive film 500 so as to be transferred to the ambience, so as to provide a better heat dissipation effect,

It is noted that, when an electrode 402 of the LED chip 400 is directly in electrical connection with the first lead frame 310, the design personnel can use the wiring distribution technique to prevent the thermal conductive film 500 from affecting the electrical connection between the LED chip 400 and the first lead frame 310. Similarly, the thermal conductive film 500 can also be extended continuously from the inner surfaces 211 of the base 200 to one end surface of the second lead frame 320 in the reflective recess 210, and the design personnel can also use the wiring distribution technique to prevent the thermal conductive film 500 from affecting the electrical connection between the LED chip 400 and the second lead frame 320.

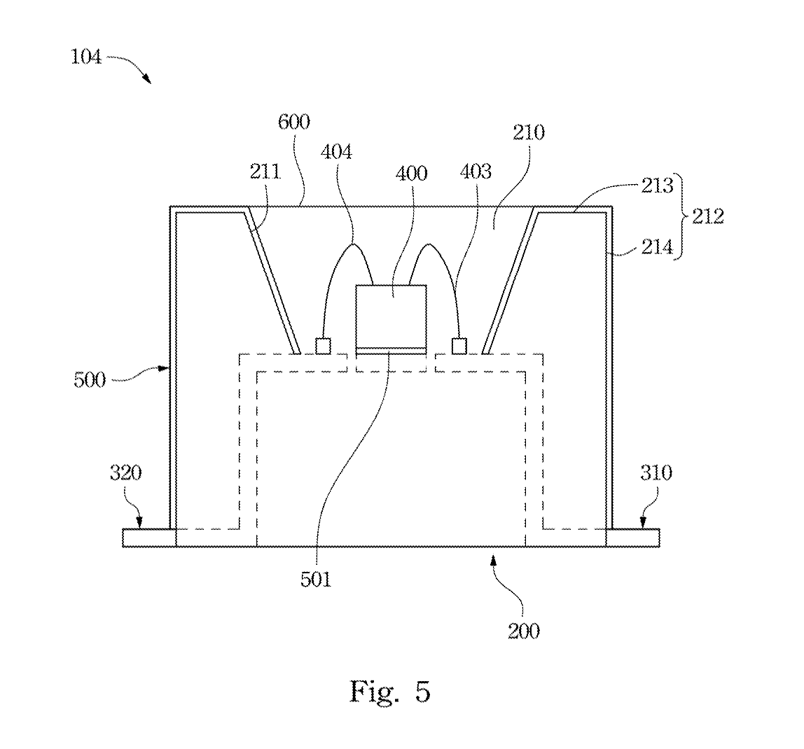

Reference is now made to FIG. 5. FIG. 5 is a side view showing the light emitting diode packaging structure 104 according to still another embodiment of the present invention.

The light emitting diode packaging structure 104 further includes a third lead frame 330. The LED chip 400 is disposed on the third lead frame 330 and is electrically isolated from third lead frame 330, and is electrically connected to the first lead frame 310 via a first conductive wire 403, and electrically connected to the second lead frame 320 via a second conductive wire 404, and therefore, the light emitting diode packaging structure 104 is equipped with a property of electro thermal separation.

Regardless of the aforementioned thermal conductive film 500 partially or completely covering the outer surfaces 212 of the base 200, one segment 501 of the thermal conductive film 500 is formed on a surface of the third lead frame 330, and is disposed between the LED chip 400 and the third lead frame 330, so as to be physically in contact with the LED chip 400.

Substantially, the thermal conductive films 500, 501 are extended continuously from the surface of the third lead frame 330 to the inner surfaces 211 (not shown in figures) of the base 200, and are extended continuously from the inner surfaces 211 of the base 200 to the outer surfaces 212 of the base 200.

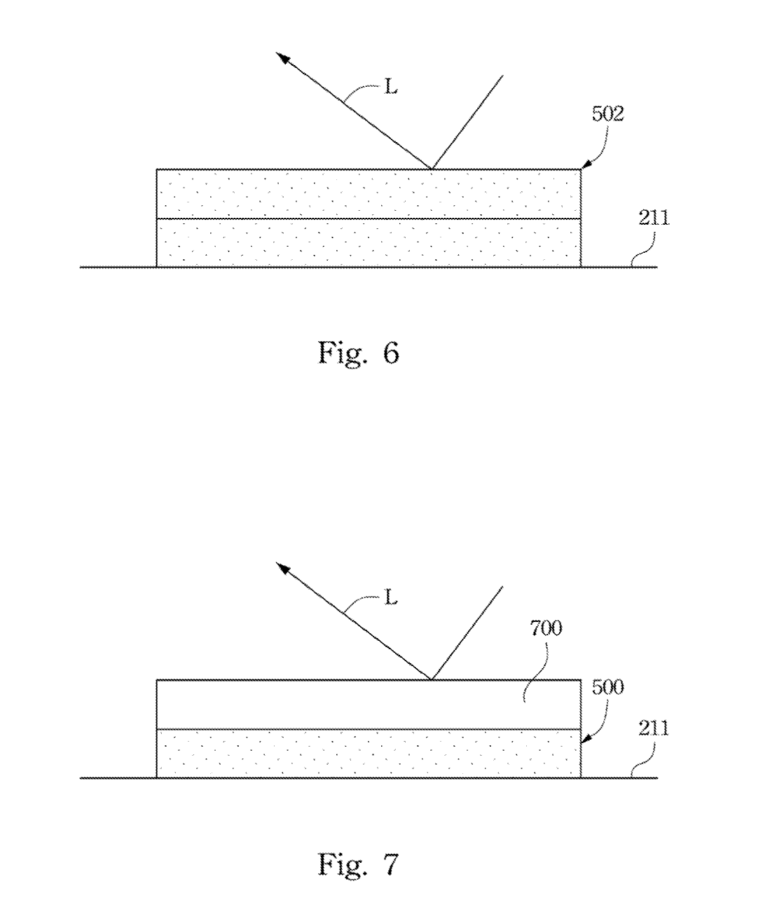

Reference is now made to FIG. 1B and FIG. 6. FIG. 6 is a schematic view showing the thermal conductive film 502 of the light emitting diode packaging structure according to still another embodiment of the present invention.

The thermal conductive films 500, 502 are not limited to a single-layer structure, such as the thermal conductive film 500 shown in FIG. 1B or a multiple-layer structure, such as the thermal conductive film 502 shown in FIG. 6. When the thermal conductive film 502 is formed as a multiple-layer structure, such as mutually-stacked multiple films, because the thermal conductive film 502 is extended continuously from the inner surfaces 211 to the outer surfaces 212 (as shown in FIG. 1A), the heat conduction performance can be enhanced so as to shorten the time of heat dissipation.

FIG. 7 is a schematic view showing the thermal conductive film 500 of the light emitting diode packaging structure according to still another embodiment of the present invention.

According to the still another embodiment, the light emitting diode packaging structure 100 further includes a light reflecting layer 700. The aforementioned light reflecting layer 700 covers or adhered on the side of the thermal conductive film 500 which is disposed opposite to the inner surfaces 211, i.e. the thermal conductive film 500 is disposed between the light reflecting layer 700 and the inner surfaces 211. The light reflecting layer 700 can partially or completely cover the thermal conductive film 500 formed on all of the inner surfaces 211 in the reflective recess 210.

As such, referring to FIG. 1A and FIG. 7, when the thermal conductive film 500 is not equipped with the light reflecting property, the light reflecting layer 700 can enhance the reflective of light L, such that the light L can be concentrated and outputted towards the opening formed in the reflective recess 210, so as to increase the overall emitted light amount of the light emitting diode packaging structure 100, and meanwhile, the thermal conductive film 500 is still equipped with the heat conduction function. However, the present invention is not limited to installing the light reflecting layer 700.

Regardless of the aforementioned thermal conductive films 500, 502 formed in the single-layer or multiple-layer structure, the thickness D of the thermal conductive film 500, 502 can be smaller than or equal to 100 micrometer, for example, as shown in FIG. 1A.

In addition, the material forming the thermal conductive film can be on single type of material or a plurality of types of materials. For example, the thermal conductive film includes an organic material, an inorganic material or a compound material; and furthermore the material forming the thermal conductive film can be diamond-like carbon, aluminum nitride, aluminum oxide or ceramic.

Reference is now made to FIG. 1B, FIG. 6 and FIG. 7. According to the disclosed embodiments, for increasing the heat dissipation effect of the thermal conductive film 500, the thermal conductive film 500 includes plural particles 510 distributed therein, and the diameter of each particle 510 can be smaller than or equal to 10 micrometer, for example.

It can be seen from the above that, with the light emitting diode packaging structure provided by the present invention, the high temperature generated by the LED chip can be rapidly decreased, thereby maintaining the service life of LED element.

To sum up, by the light emitting diode packaging structure of the present invention, the high temperature generated by a LED chip can be rapidly reduced, so as to prevent the service life of light emitting diode packaging structure from being shortened; also, due to light reflective property or at least light shielding property of the thermal conductive film, the light emitting diode packaging structure of the present invention can prevent light leakage from the excessively thin lateral wall of the light emitting diode packaging structure so as to concentrate the overall emitted light amount of the light emitting diode packaging structure.

Although the present invention has been described with reference to the preferred embodiments thereof, it is apparent to those skilled in the art that a variety of modifications and changes may be made without departing from the scope of the present invention which is intended to be defined by the appended claims.

The reader's attention is directed to all papers and documents which are filed concurrently with this specification and which are open to public inspection with this specification, and the contents of all such papers and documents are incorporated herein by reference.

All the features disclosed in this specification (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

What is claimed is:

1. A light emitting diode packaging structure, comprising:
a base comprising a reflective recess and a plurality of outer surfaces surrounding the reflective recess;
a plurality of lead frames respectively disposed in the base, and exposed in the reflective recess;
a LED chip disposed on one of the lead frames n the reflective recess;
a thermal conductive film having a light shielding property, and covering all inner surfaces of the reflective recess and at least one of the outer surfaces of the base; and
a encapsulating member filled in the reflective recess to cover the thermal conductive film and the LED chip.

2. The light emitting diode packaging structure according to claim 1, wherein the thermal conductive film partially covers at least one of the outer surfaces of the base.

3. The light emitting diode packaging structure according to claim 1, wherein the thermal conductive film completely covers all of the outer surfaces of the base.

4. The light emitting diode packaging structure according to claim 1, wherein the thermal conductive film further covers at least one of the lead frames.

5. The light emitting diode packaging structure according to claim 4, wherein the thermal conductive film further contacts the LED chip.

6. The light emitting diode packaging structure according to claim 1, wherein the thermal conductive film is formed as a single-layer or a multiple-layer.

7. The light emitting diode packaging structure according to claim 6, wherein a thickness of the thermal conductive film is smaller than or equal to 100 micrometer.

8. The light emitting diode packaging structure according to claim 1, wherein the thermal conductive film comprises one single type of material or a plurality of types of materials.

9. The light emitting diode packaging structure according to claim 8, wherein the thermal conductive film comprises an organic material, an inorganic material or a compound material.

10. The light emitting diode packaging structure according to claim 9, wherein the material forming the thermal conductive film is selected from the group consisting of diamond-like carbon, aluminum nitride, aluminum oxide and ceramic.

11. The light emitting diode packaging structure according to claim 10, wherein the thermal conductive film comprises a plurality of particles, and each of the particles has a diameter smaller than or equal to 10 micrometer.

12. The light emitting diode packaging structure according to claim 11, further comprising a light reflecting layer covering the thermal conductive film.
